(19) United States
(12) Patent Application Publication
(10) Pub. No.: US 2017/0018595 A1
(43) Pub. Date: Jan. 19, 2017

(54) METHOD OF FABRICATING LIGHT PIPE OF IMAGE SENSING DEVICE

(71) Applicant: Powerchip Technology Corporation, Hsinchu (TW)

(72) Inventors: Tzu-Wen Kao, Chiayi County (TW); Saysamone Pittikoun, Hsinchu County (TW); Yu-Yuan Lai, Miaoli County (TW); Meng-Chieh Hsieh, Kaohsiung City (TW)

(21) Appl. No.: 14/925,985

(22) Filed: Oct. 29, 2015

(30) Foreign Application Priority Data
Jul. 17, 2015 (TW) 104123229

(51) Int. Cl. H01L 27/146

(52) U.S. Cl. CPC H01L 27/14685

(57) ABSTRACT

A method of fabricating a light pipe of an image sensing device including following steps is provided. A substrate is provided. The substrate includes a pixel region and a periphery region. A light sensing region has been formed in the substrate. The light sensing region is located in the pixel region. A dielectric layer is formed on the substrate. An interconnection structure and a light-blocking metal layer have been formed in the dielectric layer. The light-blocking metal layer is located over the interconnection structure, and the light-blocking metal layer has an opening exposing the light sensing region. A portion of the dielectric layer exposed by the opening is removed by using the light-blocking metal layer as a mask to form the light pipe in the dielectric layer.

### CROSS-REFERENCE TO RELATED APPLICATION

This application claims the priority benefit of Taiwan application serial no. 104123229, filed on Jul. 17, 2015. The entirety of the above-mentioned patent application is hereby incorporated by reference herein and made a part of this specification.

### BACKGROUND OF THE INVENTION

1. Field of the Invention

The invention relates to a method of fabricating an image sensing device, in particular, to a method of fabricating a light pipe of an image sensing device.

2. Description of Related Art

The image sensing device produced by using the semiconductor process can sense the light projecting to the substrate of the semiconductor, such as complementary metal oxide semiconductor (CMOS) and so on. The image sensing device described above utilizes a sensing unit array to receive light energy and convert the light energy into digital data.

However, since the pixel size of the image sensing device keeps shrinking, when forming the light pipe which is capable to increase the optical efficiency of the image sensing device by current lithography process and etching process, the issue of alignment must be considered in the process to avoid causing damage of interconnection structure during the manufacture of the light pipe. Therefore, properly shrinking for the light pipe is required, such that the image sensing device cannot collect sufficient light, thus resulting in decrease of the optical efficiency. In addition, the light which is not collected to the light pipe may also generate disturbance between two adjacent sensing units due to refraction, thus reducing the color discrimination efficiency.

### SUMMARY OF THE INVENTION

The invention provides a method of fabricating a light pipe of an image sensing device, which can effectively improve the optical efficiency and the color discrimination efficiency of the image sensing device.

The invention provides a method of fabricating a light pipe of an image sensing device, and the method includes the following steps. A substrate is provided. The substrate includes a pixel region and a periphery region. A light sensing region has been formed in the substrate. The light sensing region is located in the pixel region. A dielectric layer is formed on the substrate. An interconnection structure and a light-blocking metal layer have been formed in the dielectric layer. The light-blocking metal layer is located over the interconnection structure, and the light-blocking metal layer has an opening exposing the light sensing region. A portion of the dielectric layer exposed by the opening is removed by using the light-blocking metal layer as a mask to form the light pipe in the dielectric layer.

According to an embodiment of the invention, in the method of fabricating the light pipe of the image sensing device, the light sensing region is, for example, a photodiode.

According to an embodiment of the invention, in the method of fabricating the light pipe of the image sensing device, a foil ling method of the interconnection structure is, for example, a damascene process or a combination of a deposition process, a lithography process and an etching process.

According to an embodiment of the invention, in the method of fabricating the light pipe of the image sensing device, a foil ling method of the light-blocking metal layer is, for example, a damascene process or a combination of a deposition process, a lithography process and an etching process.

According to an embodiment of the invention, the method of fabricating the light pipe of the image sensing device further includes forming a patterned photoresist layer on the dielectric layer before removing the portion of the dielectric layer, wherein the patterned photoresist layer exposes the pixel region and covers the periphery region.

According to an embodiment of the invention, in the method of fabricating the light pipe of the image sensing device, an exposure machine for forming the patterned photoresist layer is, for example, an exposure machine using I-line, KrF or ArF as an exposure light source.

According to an embodiment of the invention, in the method of fabricating the light pipe of the image sensing device, a removing method of the portion of the dielectric layer is, for example, a dry etching process.

According to an embodiment of the invention, the method of fabricating the light pipe of the image sensing device further includes conformally forming an oxide layer on a surface of the light pipe.

According to an embodiment of the invention, the method of fabricating the light pipe of the image sensing device further includes forming a protective layer on the oxide layer.

According to an embodiment of the invention, in the method of fabricating the light pipe of the image sensing device, a plurality of isolation regions have been formed in the substrate, and the light sensing region is located between the isolation regions.

Based on the above, in the method of fabricating the light pipe of the image sensing device provided by the invention, since the light-blocking metal layer is used as the mask to foul' the light pipe in a self-aligned method, the size of the light pipe formed by the self-aligned method is larger than the size of the light pipe formed by a non-self-aligned method. Therefore, much larger amounts of the incident light can be captured and gathered, and then improve the optical efficiency and the color discrimination efficiency. In addition, since the light pipe above the light sensing region is foamed by the self-aligned method, the problem of misalignment can be avoided and the linewidth level of the used mask can be reduced.

In order to make the aforementioned features and advantages of the invention more comprehensible, embodiments accompanying figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1D are cross-sectional views of fabrication processes of a light pipe of an image sensing device according to an embodiment of the invention.

FIG. 2 is a top view of FIG. 1B, wherein FIG. 1B is a cross-sectional view along the sectional line I-I′ in FIG. 2.

### DESCRIPTION OF THE EMBODIMENTS

Reference will now be made in detail to the exemplary embodiments of the invention, examples of which are illustrated in the accompanying drawings. Wherever possible, the same reference numbers are used in the drawings and the description to refer to the same or like parts.

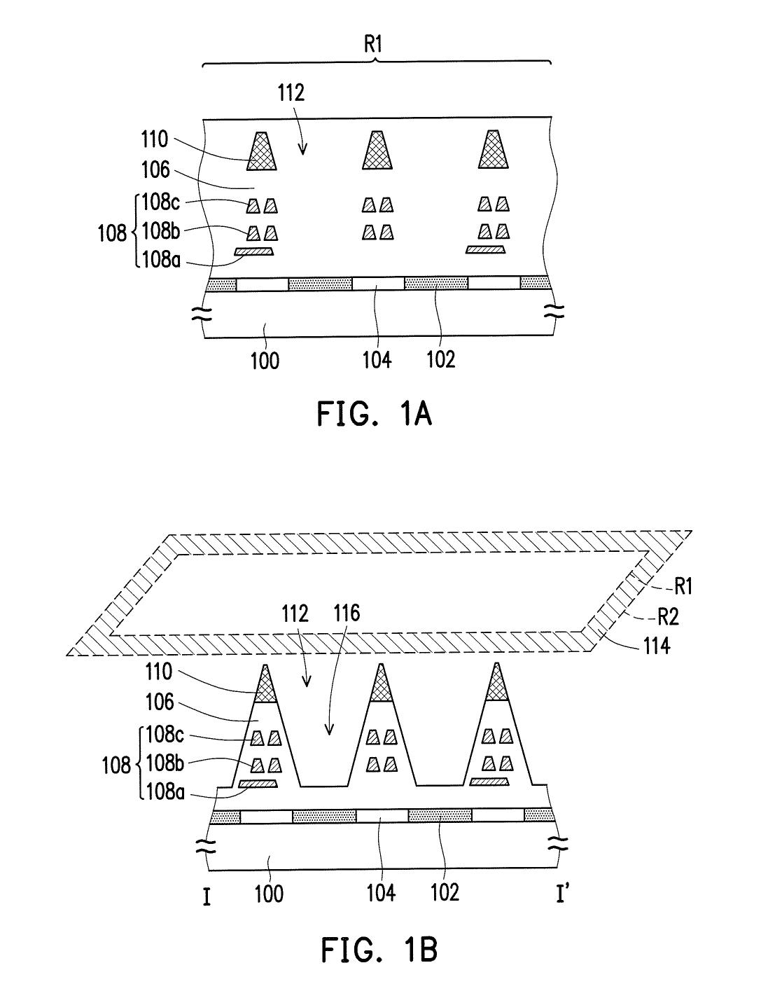

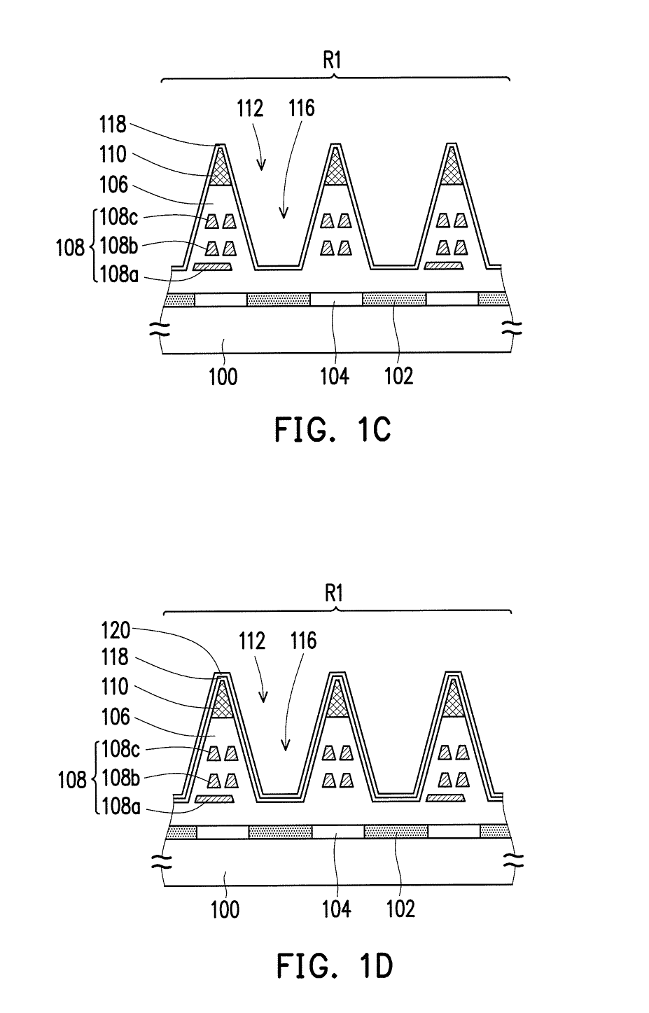

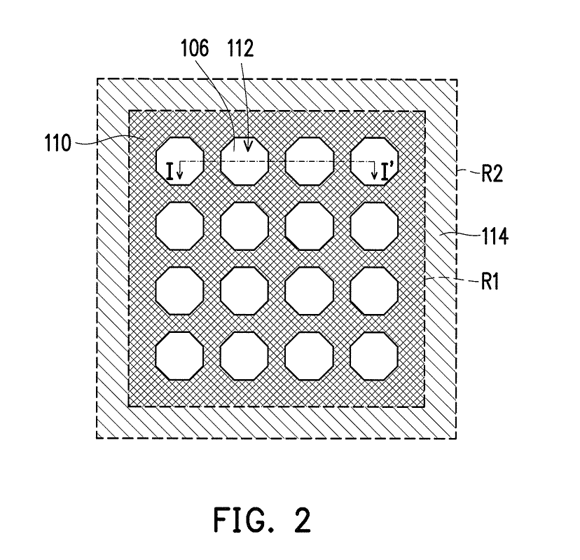

FIG. 1A to FIG. 1D are cross-sectional views of fabrication processes of a light pipe of an image sensing device according to an embodiment of the invention. FIG. 2 is a top view of FIG. 1B, wherein FIG. 1B is a cross-sectional view along the sectional line I-I′ in FIG. 2. In this embodiment, the image sensing device is, for example, a complementary metal oxide semiconductor image sensing device.

Referring to FIG. 1A, a substrate 100 is provided. The substrate 100 includes a pixel region R1 and a periphery region R2 (as showed in FIG. 1B and FIG. 2). A light sensing region 102 has been foamed in the substrate 100. The light sensing region 102 is, for example, a photodiode. The light sensing region 102 is located in the pixel region R1. In addition, a plurality of isolation regions 104 may also have been Ruined in the substrate 100. The light sensing region 102 is located between the isolation regions 104. The isolation regions 104 are, for example, shallow trench isolation structures.

A dielectric layer 106 is formed on the substrate 100. The material of the dielectric layer 106 is, for example, silicon oxide or P-TEOS. In FIG. 1A, although the dielectric layer 106 is illustrated as a single layer for description, the dielectric layer 106 actually may be a multi-layer structure. The forming method of the dielectric layer 106 is, for example, a chemical vapor deposition method.

An interconnection structure 108 and a light-blocking metal layer 110 have been formed in the dielectric layer 106. The interconnection structure 108 may be used for electrically connecting to a semiconductor device or an external power source. In this embodiment, the interconnection structure 108, for example, includes a first metal layer 108a, a second metal layer 108b and a third metal layer 108c for description, but the invention is not limited thereto. A person skilled in the art may determine the number of the metal layers of the interconnection structure 108 according to the actual product design requirements. The material of the interconnection structure 108 is, for example, copper, aluminium or tungsten. The forming method of the interconnection structure 108 is, for example, a damascene process or a combination of a deposition process, a lithography process and an etching process.

The light-blocking metal layer 110 is located over the interconnection structure 108, and the light-blocking metal layer 110 has an opening 112 exposing the light sensing region 102. After the light pipe is subsequently formed, the light-blocking metal layer 110 may prevent the incident light of the specific sensing unit to be entered from hitting another sensing unit in order to inhibit the light interference. The light-blocking metal layer 110 may be formed in the same process of forming the interconnection metal layer of the periphery region R2 at the same time. Therefore, the light-blocking metal layer 110 may be formed without an additional metal process so that the complexity of the process may be reduced, but the invention is not limited thereto. In this embodiment, the light-blocking metal layer 110 is, for example, formed with the top metal layer of the interconnection structure of the periphery region R2 at the same time. In other embodiments, the light-blocking metal layer 110 may also be formed by an individual metal process. The material of the light-blocking metal layer 110 is, for example, copper, aluminium or tungsten. The following method of the light-blocking metal layer 110 is, for example, a damascene process or a combination of a deposition process, a lithography process and an etching process.

Referring to FIG. 1B and FIG. 2 at the same time, a patterned photoresist layer 114 exposing the pixel region R1 and covering the periphery region R2 may be formed on the dielectric layer 106. The patterned photoresist layer 114 may be used for protecting the periphery region R2 during the following process of forming the light pipe. The forming method of the patterned photoresist layer 114 is, for example, performing a lithography process. The exposure machine used for forming the patterned photoresist layer 114 is, for example, the exposure machine using I-line, KrF or ArF as an exposure light source. In addition, the patterned photoresist layer 114 of this embodiment exposes the pixel region R1 which is a large area, unlike the conventional patterned photoresist layer that only exposes a small area for forming the light pipe. Therefore, the exposure machine using I-line as the exposure light source may also be used in this embodiment, such that the production cost can be reduced.

A portion of the dielectric layer 106 which is exposed by the opening 112 is removed by using the patterned photoresist layer 114 and the light-blocking metal layer 110 as a mask to form a light pipe 116 in the dielectric layer 106. In this embodiment, the opening 112 may also be used as a portion of the light pipe 116. In addition, during the process of forming the light pipe 116, a portion of the light-blocking metal layer 110 may be consumed.

Furthermore, the number of the openings 112 of the light-blocking metal layer 110 is designed to correspond to the number of the light sensing regions 102. In this embodiment, although the number of the openings 112 of the light-blocking metal layer 110 is sixteen as an example for description, the invention is not limited thereto. As long as the number of the openings 112 is one or more, it belongs to the protection scope of the invention. The removing method of the portion of the dielectric layer 106 is, for example, a dry etching process. In addition, here the top view shape of the opening 112 of the light-blocking metal layer 110 is an octagonal shape as an example for description, but the invention is not limited thereto. In other embodiments, the top view shape of the opening 112 may also be a circular shape or an elliptic shape.

In FIG. 1B, although the depth of the light pipe 116 reaches the depth position of the first metal layer 108a for description, the invention is not limited thereto. A person skilled in the art may determine the depth of the light pipe 116 according to the actual product design requirements.

According to the description above, it is known that during the process steps of forming the light pipe 116, since the light-blocking metal layer 110 is used as the mask to form the light pipe 116 in the self-aligned method, the size of the light pipe 116 formed by the self-aligned method is larger than the size of the light pipe formed by the non-self-aligned method which is the conventional technique. Therefore, much larger amounts of the incident light can be captured and gathered, and then the optical efficiency and color discrimination efficiency are improved. In addition, since the light pipe 116 is formed above the light sensing region 102 by the self-aligned method, the problem of misalignment can be avoided and the linewidth level of the used mask can be reduced.

In addition, this embodiment may also optimize the process by adjusting the layout of the light-blocking metal layer 110. For example, the layout of the light-blocking metal layer 110 may be designed to be able to protect the interconnection structure 108 below the light-blocking metal layer 110 during the process of forming the light pipe 116.

Referring to FIG. 1C, the patterned photoresist layer 114 may be removed. The removing method of the patterned photoresist layer 114 is, for example, a dry-type photoresist removing method.

An oxide layer 118 may be formed conformally on the surface of the light pipe 116. Under the condition of Snell's law, the oxide layer 118 can totally reflect the incident light to improve the optical efficiency. The material of the oxide layer 118 is, for example, silicon oxide, such as P-TEOS. The forming method of the oxide layer 118 is, for example, a chemical vapor deposition method.

Referring to FIG. 1D, a protective layer 120 may be formed on the oxide layer 118. The protective layer 120 may be used for preventing the moisture from entering the device to improve the reliability of the device. The material of the protective layer 120 is, for example, silicon nitride. The forming method of the protective layer 120 is, for example, a chemical vapor deposition method.

In sum, in the method of fabricating the light pipe of the image sensing device of the embodiments above, since the light-blocking metal layer 110 is used as the mask to form the light pipe 116 having the larger size in the self-aligned method, much larger amounts of the incident light can be captured and gathered, and then the optical efficiency and color discrimination efficiency can be improved. In addition, the self-aligned type light pipe 116 formed by the embodiments described above can avoid the problem of misalignment and reduce the linewidth level of the used mask.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

1. A method of fabricating a light pipe of an image sensing device, the method comprising:
providing a substrate comprising a pixel region and a periphery region, wherein a light sensing region has been formed in the substrate, and the light sensing region is located in the pixel region;
forming a dielectric layer on the substrate, wherein an interconnection structure and a light-blocking metal layer have been formed in the dielectric layer, and the light-blocking metal layer is located over the interconnection structure, and the light-blocking metal layer has an opening exposing the light sensing region;
removing a portion of the dielectric layer exposed by the opening by using the light-blocking metal layer as a mask to form the light pipe in the dielectric layer;
conformally forming an oxide layer on a surface of the light pipe; and
conformally forming a protective layer on the oxide layer,
wherein at least a portion of the protective layer is located inside the light pipe.

2. The method of claim 1, wherein the light sensing region comprises a photodiode.

3. The method of claim 1, wherein a forming method of the interconnection structure comprises a damascene process or a combination of a deposition process, a lithography process and an etching process.

4. The method of claim 1, wherein a forming method of the light-blocking metal layer comprises a damascene process or a combination of a deposition process, a lithography process and an etching process.

5. The method of claim 1, further comprising:
forming a patterned photoresist layer on the dielectric layer before removing the portion of the dielectric layer, wherein the patterned photoresist layer exposes the pixel region and covers the periphery region.

6. The method of claim 5, wherein an exposure machine for forming the patterned photoresist layer comprises an exposure machine using I-line, KrF or ArF as an exposure light source.

7. The method of claim 1, a removing method of the portion of the dielectric layer comprises a dry etching process.

8-9. (canceled)

10. The method of claim 1, wherein a plurality of isolation regions have been formed in the substrate, and the light sensing region is located between the isolation regions.
